(19) United States
(12) Patent Application Publication
(10) Pub. No.: US 2024/0055554 A1
(43) Pub. Date: Feb. 15, 2024

(54) DISPLAY DEVICE AND MANUFACTURING METHOD THEREOF

(71) Applicant: Samsung Display Co., LTD., Yongin-si (KR)

(72) Inventors: Se Hyun LEE, Yongin-si (KR); Jin Joo HA, Yongin-si (KR)

(73) Assignee: Samsung Display Co., LTD., Yongin-si (KR)

(21) Appl. No.: 18/327,219

(22) Filed: Jun. 1, 2023

(30) Foreign Application Priority Data
Aug. 12, 2022 (KR) 10-2022-0101408

(51) Int. Cl. H01L 33/10; H01L 33/50; H01L 33/62; H01L 33/00

(52) U.S. Cl. CPC H01L 33/10; H01L 33/508; H01L 33/62; H01L 33/0075; H01L 33/06

(57) ABSTRACT

A display device includes a light blocking layer surrounding a light emitting area; a light emitting element disposed in the light emitting area; and a reflective layer disposed on the light emitting element, and a width of the light emitting area in a first direction is less than a width of the light emitting area in a second direction, and heights of first areas of the reflective layer facing each other in the first direction are greater than heights of second areas of the reflective layer facing each other in the second direction.

### CROSS-REFERENCE TO RELATED APPLICATION(S)

This application claims priority to and benefits of Korean Patent Application No. 10-2022-0101408 under 35 U.S.C. § 119 filed in the Korean Intellectual Property Office on Aug. 12, 2022, the entire contents of which are incorporated herein by reference.

### BACKGROUND

### 1. Technical Field

The disclosure relates to a display device and a manufacturing method thereof.

### 2. Description of the Related Art

Recently, as interest in an information display is increasing, research and development for display devices are continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device and a manufacturing method thereof that may improve light efficiency.

Embodiments are not limited to the embodiments mentioned above, and other technical objects may be clearly understood to a person of an ordinary skill in the art by the following description.

An embodiment provides a display device that may include a light blocking layer surrounding a light emitting area; a light emitting element disposed in the light emitting area; and a reflective layer disposed on the light emitting element, wherein a width of the light emitting area in a first direction is less than a width of the light emitting area in a second direction, and heights of first areas of the reflective layer facing each other in the first direction are greater than heights of second areas of the reflective layer facing each other in the second direction.

The reflective layer may be disposed directly on a surface of the light emitting element.

The light blocking layer may include an opening having a same planar shape as the light emitting area, and the display device may further include a color filter disposed in the opening of the light blocking layer.

The display device may further include a color converting layer disposed between the light emitting element and the color filter.

The display device may further include an organic layer surrounding the light emitting element.

The reflective layer may be disposed between the light emitting element and the organic layer.

The organic layer may be disposed directly on the reflective layer.

The light emitting element may include a first semiconductor layer; a second semiconductor layer; and an active layer disposed between the first semiconductor layer and the second semiconductor layer.

The second areas of the reflective layer may at least partially expose the second semiconductor layer.

The display device may further include a first electrode disposed on the first semiconductor layer; and a second electrode disposed on the second semiconductor layer.

An embodiment may include providing a light emitting element in a light emitting area; forming a reflective layer on the light emitting element; forming a photoresist pattern on first areas of the reflective layer; and partially etching second areas of the reflective layer, wherein a width of the light emitting area in a first direction is less than a width of the light emitting area in a second direction, and the first areas of the reflective layer face each other in the first direction, and the second areas of the reflective layer face each other in the second direction.

The manufacturing method of the display device may further include forming a color filter on the light emitting element.

The manufacturing method of the display device may further include forming a light blocking layer surrounding the light emitting area.

The light blocking layer may include an opening having a same planar shape as the light emitting area.

The color filter may be formed within the opening of the light blocking layer.

The manufacturing method of the display device may further include forming a color converting layer on the light emitting element.

The manufacturing method of the display device may further include forming a first organic layer fixing the light emitting element.

The manufacturing method of the display device may further include forming a second organic layer on the first organic layer.

The second organic layer may surround the light emitting element.

The second organic layer may be formed directly on the reflective layer.

Other embodiments are included in the detailed description and drawings.

According to an embodiment, it is possible to improve light efficiency by forming different heights of a reflective layer formed on a side surface of a light emitting element according to a width of a light emitting area.

Effects of embodiments are not limited by what is illustrated in the above, and more various effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 illustrates a schematic top plan view of a display device according to an embodiment.

FIG. 2 illustrates a schematic top plan view of a pixel unit according to an embodiment.

FIG. 3 illustrates a schematic diagram of an equivalent circuit of a pixel according to an embodiment.

FIG. 4 illustrates a schematic cross-sectional view taken along line A-A′ of FIG. 2.

FIG. 5 illustrates a schematic top plan view of a reflective layer according to an embodiment.

FIG. 6 illustrates a schematic cross-sectional view taken along line B-B′ of FIG. 5.

FIG. 7 illustrates a schematic cross-sectional view taken along line C-C′ of FIG. 5.

FIG. 8 to FIG. 20 illustrate schematic top plan views and schematic cross-sectional views of process steps of a manufacturing method of a display device according to an embodiment.

### DETAILED DESCRIPTION OF THE EMBODIMENTS

Advantages and features of the disclosure and methods of accomplishing the same may be understood more readily by reference to the following detailed description of embodiments and the accompanying drawings. The disclosure may, however, be embodied in different forms and should not be construed as limited to the embodiments set forth herein. Embodiments are provided so that this disclosure will be thorough and complete, and will fully convey the scope of the disclosure to those skilled in the art, and further, the disclosure may be defined by the claims.

The terms used herein are for the purpose of describing embodiments only and is not intended to be limiting.

In the drawings, sizes, thicknesses, ratios, and dimensions of the elements may be exaggerated for ease of description and for clarity. Like numbers refer to like elements throughout.

As used herein, the singular forms “a”, “an” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The term “connection” or “coupling” may comprehensively mean a physical and/or electrical connection or coupling. Further, this may comprehensively mean a direct or indirect connection or coupling, and an integrated or non-integrated connection or coupling.

It will be understood that when an element or a layer is referred to as being ‘on’ another element or layer, it can be directly on another element or layer, or intervening element or layer may also be present. Throughout the specification, the same reference numerals denote the same constituent elements.

Although the terms “first”, “second”, and the like are used to describe various constituent elements, these constituent elements are not limited by these terms. These terms are used only to distinguish one constituent element from another constituent element. Therefore, the first constituent elements described below may be the second constituent elements within the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings.

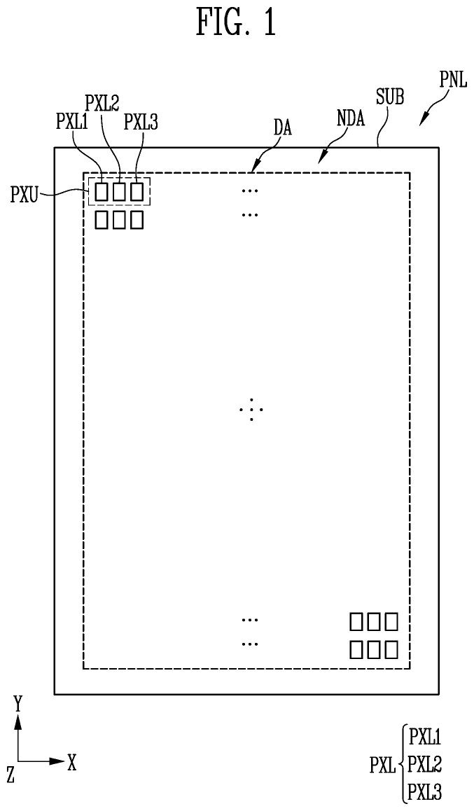

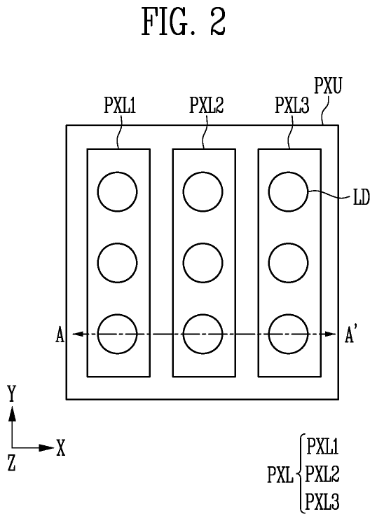

FIG. 1 illustrates a schematic top plan view of a display device according to an embodiment. FIG. 2 illustrates a schematic top plan view of a pixel unit according to an embodiment.

FIG. 1 illustrates a display panel PNL provided in the display device. For better understanding and ease of description, FIG. 1 illustrates a structure of the display panel PNL based on a display area DA. However, in an embodiment, at least one driving circuit portion (for example, at least one of a scan driver and a data driver), wires, and/or pads may be further disposed in the display panel PNL.

Referring to FIG. 1 and FIG. 2, the display panel PNL and a substrate SUB for forming the display panel may include the display area DA for displaying an image and a non-display area NDA excluding the display area DA. The display area DA may form a screen on which an image is displayed, and the non-display area NDA may be the remaining area except for the display area DA.

A pixel unit PXU may be disposed in the display area DA. The pixel unit PXU may include a first pixel PXL1, a second pixel PXL2, and/or a third pixel PXL3. Hereinafter, when arbitrarily referring to at least one of the first pixel PXL1, the second pixel PXL2, and the third pixel PXL3, or when comprehensively referring to two or more types of pixels thereof, they will be referred to as a “pixel PXL” or “pixels PXL”.

The pixels PXL may be regularly arranged (or disposed) according to a stripe or PENTILE™ arrangement structure. However, the arrangement structure of the pixels PXL is not limited thereto, and the pixels PXL may be arranged in the display area DA in various structures and/or methods.

In an embodiment, two or more types of pixels PXL emitting light of different colors may be disposed in the display area DA. For example, in the display area DA, the first pixels PXL1 emitting light of the first color, the second pixels PXL2 emitting light of the second color, and the third pixels PXL3 emitting light of the third color may be arranged. At least one first to third pixels PXL1, PXL2, and PXL3 disposed to be adjacent to each other may form one pixel unit PXU that may emit light of various colors. For example, the first pixel PXL1 may be a red pixel that emits red light, the second pixel PXL2 may be a green pixel that emits green light, and the third pixel PXL3 may be a blue pixel that emits blue light, but the disclosure is not limited thereto. FIG. 1 and FIG. 2 illustrate a case in which the pixel unit PXU may include one first pixel PXL1, one second pixel PXL2, and one third pixel PXL3, but the disclosure is not necessarily limited thereto, and the pixel unit PXU may include one first pixel PXL1, two second pixels PXL2, and one third pixel PXL3.

The first pixel PXL1, the second pixel PXL2, and the third pixel PXL3 are provided with light emitting elements LD of a same color, and include color converting layers of different colors disposed on respective light emitting elements LD, so that they may emit light of the first color, the second color, and the third color, respectively.

The first pixel PXL1, the second pixel PXL2, and the third pixel PXL3 are each provided with a first color light emitting element LD, a second color light emitting element LD, and a third color light emitting element LD as a light source, so that they respectively emit light of the first color, light of the second color, and light of the third color. However, the color of light emitted by each pixel PXL may be variously changed.

The pixel PXL may include at least one light emitting element LD driven by a control signal (for example, a scan signal and a data signal) and/or a power source (for example, a first power source and a second power source). The pixel PXL may be an active pixel. However, the type, structure, and/or driving method of pixels PXL that may be applied to the display device are not particularly limited. For example, each pixel PXL may be a pixel of a passive or active light emitting display device of various structures and/or driving methods.

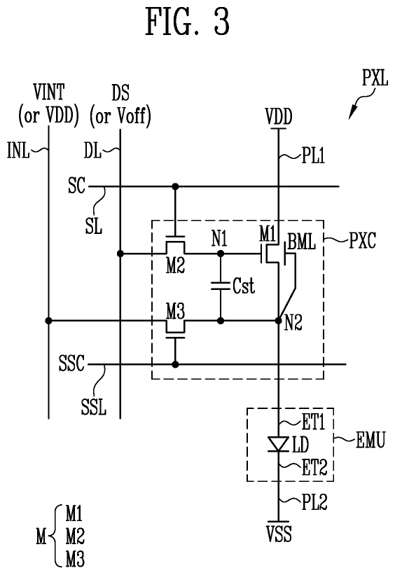

FIG. 3 illustrates a schematic diagram of an equivalent circuit a pixel according to an embodiment.

In an embodiment, each pixel PXL shown in FIG. 3 may be one of the pixels PXL of FIG. 1 and FIG. 2. For example, the pixel PXL of FIG. 3 may be one of the first pixel PXL1, the second pixel PXL2, and the third pixel PXL3. In an embodiment, the pixels PXL disposed in the display area DA may have substantially the same or similar structure. The pixels PXL may have various structures in addition to the structures disclosed in the embodiment of FIG. 3.

Referring to FIG. 3, the pixel PXL may be electrically connected to a scan line SL and a data line DL. The pixel PXL may be electrically connected to a first power source VDD (or a first power line PL1) and a second power source VSS (or a second power line PL2). In the embodiment, the pixel PXL may be further connected to at least one other signal line and/or power line. For example, the pixel PXL may be electrically connected to a control line SSL and an initialization power line INL to which a voltage of an initialization power source VINT is applied.

The pixel PXL may include a light emitting part EMU for generating light of a luminance corresponding to each data signal DS (or Voff). The pixel PXL may further include a pixel circuit PXC for driving the light emitting part EMU.

The light emitting part EMU may include a first electrode ET1, a second electrode ET2, and at least one light emitting element LD electrically connected between the first and second electrodes ET1 and ET2. The light emitting element LD may be electrically connected to the first power source VDD through the first electrode ET1 and/or the pixel circuit PXC, and may be electrically connected to the second power source VSS through the second electrode ET2.

The first power source VDD and the second power source VSS may supply voltages of different potentials. A potential difference between the first power source VDD and the second power source VSS may be greater than or equal to a threshold voltage of the light emitting element LD.

In the embodiment, the light emitting part EMU may include a single light emitting element LD connected in a forward direction between the pixel circuit PXC and the second power source VSS. In an embodiment, the light emitting part EMU may include light emitting elements LD that are connected in a forward direction between the first power source VDD and the second power source VSS. For example, the light emitting part EMU may include light emitting elements LD that are connected in parallel, in series, or in parallel-series between the pixel circuit PXC and the second power source VSS. In the embodiment, each light emitting element LD may be an inorganic light emitting diode manufactured with a small size ranging from nanometers to micrometers by using a nitride-based semiconductor material or a phosphide-based semiconductor material, but is not limited necessarily thereto. The type, connection structure, and/or number of the light emitting elements LD forming the light emitting part EMU may be variously changed according to embodiments.

At least one light emitting element LD connected to in a forward direction between the first power source VDD and the second power source VSS may form an effective light source of each pixel PXL. When a driving current is supplied to each light emitting element LD through the pixel circuit PXC of the corresponding pixel PXL, the light emitting element LD may emit light with a luminance corresponding to the driving current. Accordingly, the pixel PXL may emit light with a luminance corresponding to the driving current.

The pixel circuit PXC may be electrically connected between the first power source VDD and the light emitting part EMU. The pixel circuit PXC may be electrically connected to the scan line SL and the data line DL, and may be supplied with a scan signal SC and a data signal DS from the scan line SL and the data line DL, respectively. The pixel circuit PXC may be electrically connected to the control line SSL and the initialization power line INL, and may be supplied with a control signal SSC and the voltage of the initialization power source VINT from the control line SSL and the initialization power line INL, respectively.

The pixel circuit PXC may include at least one transistor M and a capacitor Cst. For example, the pixel circuit PXC may include a first transistor M1, a second transistor M2, a third transistor M3, and the capacitor Cst.

The first transistor M1 may be electrically connected between the first power source VDD and a second node N2. The second node N2 may be a node at which the pixel circuit PXC and the light emitting part EMU are connected to each other. For example, the second node N2 may be a node at which one electrode (for example, a source electrode) of the first transistor M1 and the first electrode ET1 of the light emitting part EMU (for example, an anode of the light emitting part EMU) are connected to each other. A gate electrode of the first transistor M1 may be electrically connected to a first node N1.

The first transistor M1 may be a driving transistor of each pixel PXL. For example, the first transistor M1 may be electrically connected between the first power line PL1 and the first electrode ET1 of each pixel PXL to control a driving current supplied to the light emitting part EMU in response to a voltage of the first node N1.

In the embodiment, the first transistor M1 may further include a bottom conductive layer BML (also referred to as a “back gate electrode”). In the embodiment, the bottom conductive layer BML may be electrically connected to one electrode (for example, a source electrode) of the first transistor M1.

In the embodiment in which the first transistor M1 may include the bottom conductive layer BML, by applying a back-biasing voltage to the bottom conductive layer BML of the first transistor M1, a back-biasing technique (or a sync technique) of moving a threshold voltage of the first transistor M1 in a negative or positive direction may be applied. In case that the bottom conductive layer BML is disposed to overlap a semiconductor pattern forming a channel of the first transistor M1, light incident on the semiconductor pattern is blocked, thereby stabilizing an operational characteristic of the first transistor M1.

The second transistor M2 may be electrically connected between the data line DL and the first node N1. A gate electrode of the second transistor M2 may be electrically connected to the scan line SL of the corresponding horizontal line. When the scan signal SC of a gate-on voltage (for example, a logic high voltage or a high level voltage) is supplied from the scan line SL, the second transistor M2 may be turned on to electrically connected connect the data line DL and the first node N1.

The second transistor M2 may be a switching transistor for transmitting each data signal DS to the inside of the pixel PXL. For example, for each frame period, the data signal DS of the corresponding frame is supplied to the data line DL, and the data signal DS may be transmitted to the first node N1 through the second transistor M2 during a period in which the scan signal SC of the gate-on voltage is supplied. For example, for each horizontal period forming each frame period, the scan signal SC of a gate-on voltage may be simultaneously supplied to the pixels PXL of a horizontal line corresponding to the corresponding horizontal period. Accordingly, the second transistors M2 provided to the pixels PXL of the corresponding horizontal line are turned on, so that respective data signals DS supplied to the data lines DL may be simultaneously supplied to the pixels PX of the corresponding horizontal line.

A first electrode of the capacitor Cst may be electrically connected to the first node N1. A second electrode of the capacitor Cst may be electrically connected to the second node N2. The capacitor Cst may be a storage capacitor for storing each data signal DS inside the pixel PXL. For example, the capacitor Cst may be charged with a voltage corresponding to the data signal DS supplied to the first node N1 during each frame period.

The third transistor M3 may be electrically connected between the second node N2 and the initialization power line INL. A gate electrode of the third transistor M3 may be electrically connected to the control line SSL of the corresponding horizontal line.

The third transistor M3 may be an initialization transistor that transmits the voltage of the initialization power source VINT to the first electrode ET1 of each pixel PXL during the driving period of the display panel PNL. For example, the third transistor M3 may be turned on by the control signal SSC of a gate-on voltage supplied to a corresponding pixel row. When the third transistor M3 is turned on, the voltage of the initialization power source VINT during the driving period of the display panel PNL may be transmitted to each first electrode ET1.

In the embodiment, the scan signals SC of the gate-on voltage may be sequentially supplied to the scan lines SL of respective pixel rows arranged in the display area DA during the driving period of the display panel PNL. The control signals SSC of the gate-on voltage may be sequentially supplied to the control lines SSL of respective pixel rows to be synchronized with the scan signals SC of the gate-on voltage. Accordingly, in each horizontal period, the second and third transistors M2 and M3 of the pixels PXL arranged in the corresponding horizontal line are turned on to turn on, so that voltages (for example, a voltage difference between the voltage of the data signal DS corresponding to each pixel PXL and the voltage of the initialization power source VINT) corresponding to the respective data signals DS supplied to the respective data lines DL may be stored in respective capacitors Cst.

The third transistor M3 may be turned on by the control signal SSC of the gate-on voltage supplied to the corresponding pixel row during the sensing period for detecting the characteristic and the like of each pixel PXL. When the third transistor M3 is turned on, the second node N2 may be electrically connected to the initialization power line INL. During the sensing period, the initialization power line INL may be connected to a sensing circuit. Accordingly, the voltage of the second node N2 may be transmitted to the sensing circuit through the initialization power line INL. The voltage of the second node N2 transmitted to the initialization power line INL may be provided to a driving circuit (for example, a timing controller) via the sensing circuit to be used to compensate for characteristic deviation of the pixels PXL.

In the embodiment, the control signals SSC of the gate-on voltage may be sequentially supplied to the control lines SSL of respective pixel rows arranged in the display area DA during the sensing period for detecting the characteristic and the like of the pixels PXL. Accordingly, in each horizontal period, the second nodes N2 of pixels PXL arranged in the corresponding pixel row may be connected to the sensing circuit. Accordingly, the characteristic of the pixels PXL may be detected through the initialization power line INL during the sensing period.

In FIG. 3, all of the transistors M included in the pixel circuit PXC are illustrated as n-type transistors, but the disclosure is not necessarily limited thereto. For example, at least one of the first, second, and third transistors M1, M2, and M3 may be changed to a p-type transistor. The structure and driving method of the pixel circuit PXC and/or the pixel PXL may be variously changed according to embodiments.

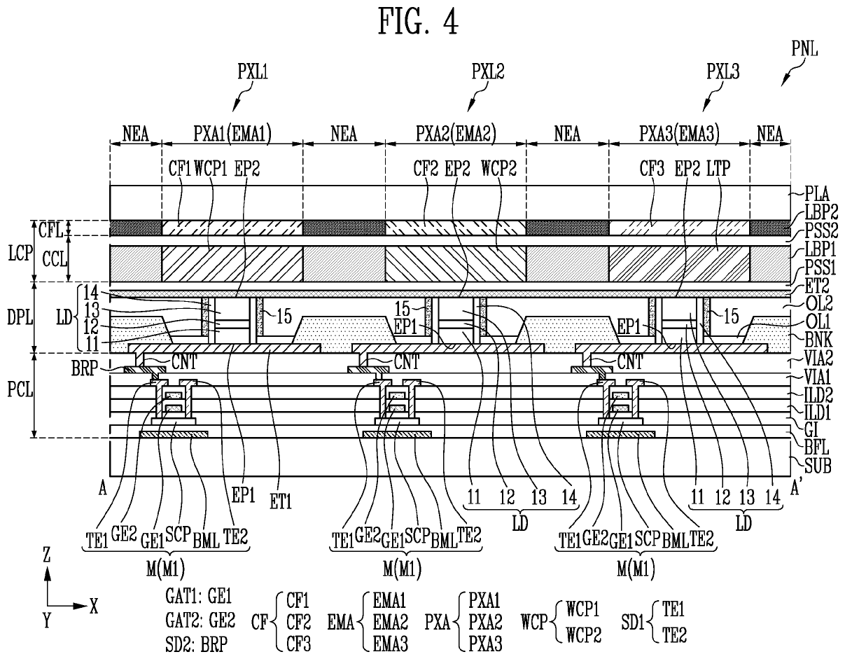

FIG. 4 illustrates a schematic cross-sectional view taken along line A-A′ of FIG. 2.

For better understanding and ease of description, FIG. 4 illustrates a pixel area PXA in which the pixel PXL is disposed centered on a light emitting area EMA of each pixel PXL. However, each pixel area PXA may include a pixel circuit area in which circuit elements forming each pixel circuit PXC are disposed, and the light emitting area EMA in which at least one light emitting element LD forming each light emitting part EMU is disposed. For example, a first pixel area PXA1 in which the first pixel PXL1 is disposed may include a first light emitting area EMA1, a second pixel area PXA2 in which the second pixel PXL2 is disposed may include a second light emitting area EMA2, and a third pixel area PXA3 in which the third pixel PXL3 is disposed may include a third light emitting area EMA3. A non-light emitting area NEA may be positioned between the first light emitting area EMA1, the second light emitting area EMA2, and the third light emitting area EMA3.

Referring to FIG. 4, the display panel PNL may include a substrate SUB, and a pixel circuit part PCL, a display element part DPL, and a light controller LCP that are sequentially disposed on the substrate SUB.

The pixel circuit part PCL may be provided on one surface or a surface of the substrate SUB. The pixel circuit part PCL may include circuit elements forming each pixel PXL. For example, the transistors M and the capacitor Cst forming the pixel circuit PXC of the corresponding pixel PXL may be formed in each pixel area PXA of the pixel circuit part PCL.

FIG. 4 illustrates, as an example of the circuit elements that may be provided in each pixel area PXA of the pixel circuit part PCL, one transistor M connected to each light emitting element LD (for example, the first transistor M1 including the bottom conductive layer BML).

The pixel circuit part PCL may include various signal lines, power lines, and/or pads connected to the pixels PXL. The pixel circuit part PCL may include conductive layers forming various signal lines, power lines, and/or pads. The pixel circuit part PCL may further include insulating layers each disposed between the conductive layers.

The bottom conductive layer BML may be disposed on the substrate SUB. The bottom conductive layer BML may be formed as a single layer or multilayer made of at least one of molybdenum (Mo), copper (Cu), aluminum (Al), chromium (Cr), gold (Au), titanium (Ti), nickel (Ni), neodymium (Nd), and an indium tin oxide (ITO) or an alloy thereof.

A buffer layer BFL may be disposed on the bottom conductive layer BML. The buffer layer BFL may prevent impurities from diffusing into the circuit element. The buffer layer BFL may be formed as a single layer, but may also be formed as a multilayer of at least double layers or more. When the buffer layer BFL is formed as the multilayer, respective layers may be made of a same material or a similar material or different materials.

A semiconductor pattern SCP may be disposed on the buffer layer BFL. For example, the semiconductor pattern SCP may include a first area contacting a first transistor electrode TE1, a second area contacting a second transistor electrode TE2, and a channel area disposed between the first and second areas. In an embodiment, one of the first and second areas may be a source area, and the other thereof may be a drain area.

In an embodiment, the semiconductor pattern SCP may be made of polysilicon, amorphous silicon, an oxide semiconductor, or the like within the spirit and the scope of the disclosure. The channel area of the semiconductor pattern SCP may be an intrinsic semiconductor as a semiconductor pattern that is not doped with impurities, and each of the first and second areas of the semiconductor pattern SCP may be a semiconductor doped with impurities.

A gate insulating layer GI may be disposed on the buffer layer BFL and the semiconductor pattern SCP. For example, the gate insulating layer GI may be disposed between the semiconductor pattern SCP and a first gate electrode GE1. The gate insulating layer GI may be a single layer or multilayer, and may include a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), or a titanium oxide (TiOₓ), and various types of inorganic materials.

A first gate conductive layer GAT1 may be disposed on the gate insulating layer GI. The first gate conductive layer GAT1 may include the first gate electrode GE1 of the transistor M. The first gate electrode GE1 may be disposed to overlap the semiconductor pattern SCP in a third direction (a Z-axis direction) on the gate insulating layer GI.

The first gate conductive layer GAT1 may be formed as a single layer or a multilayer made of at least one of titanium (Ti), copper (Cu), an indium tin oxide (ITO), molybdenum (Mo), chromium (Cr), gold (Au), nickel (Ni), and neodymium (Nd) or an alloy thereof. For example, the first gate conductive layer GAT1 may be formed as a multilayer in which titanium (Ti), copper (Cu), and/or an indium tin oxide (ITO) may be sequentially or repeatedly stacked each other.

A first interlayer insulating layer ILD1 may be disposed on the first gate conductive layer GAT1. For example, the first interlayer insulating layer ILD1 may be disposed between the first gate electrode GE1 and the first and second transistor electrodes TE1 and TE2.

The first interlayer insulating layer ILD1 may be a single layer or a multilayer, and may include a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), or a titanium oxide (TiOₓ), and various types of inorganic materials.

A second gate conductive layer GAT2 may be disposed on the first interlayer insulating layer ILD1. The second gate conductive layer GAT2 may include a second gate electrode GE2 of the transistor M. The second gate electrode GE2 may be disposed. The second gate electrode GE2 may overlap the first gate electrode GE1 in the third direction (the Z-axis direction) with the first interlayer insulating layer ILD1 interposed therebetween.

The second gate conductive layer GAT2 may be formed as a single layer or a multilayer made of at least one of titanium (Ti), copper (Cu), an indium tin oxide (ITO), molybdenum (Mo), chromium (Cr), gold (Au), nickel (Ni), and neodymium (Nd) or an alloy thereof. For example, the second gate conductive layer GAT2 may be formed as a multilayer in which titanium (Ti), copper (Cu), and/or an indium tin oxide (ITO) may be sequentially or repeatedly stacked each other.

A second interlayer insulating layer ILD2 may be disposed on the second gate conductive layer GAT2. For example, the second interlayer insulating layer ILD2 may be disposed between the second gate electrode GE2 and the first and second transistor electrodes TE1 and TE2.

The second interlayer insulating layer ILD2 may be a single layer or a multilayer, and may include a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), or a titanium oxide (TiOₓ), and various types of inorganic materials.

A first source drain conductive layer SD1 may be disposed on the second interlayer insulating layer ILD2. The first source drain conductive layer SD1 may include the first and second transistor electrodes TE1 and TE2 of the transistor M. The first and second transistor electrodes TE1 and TE2 may be disposed to overlap the semiconductor pattern SCP in the third direction (the Z-axis direction). The first and second transistor electrodes TE1 and TE2 may be electrically connected to the semiconductor pattern SCP. For example, the first transistor electrode TE1 may be electrically connected to a first area of the semiconductor pattern SCP through a contact hole penetrating the second interlayer insulating layer ILD2, the first interlayer insulating layer ILD1, and/or the gate insulating layer GI. The second transistor electrode TE2 may be electrically connected to a second area of the semiconductor pattern SCP through a contact hole penetrating the second interlayer insulating layer ILD2, the first interlayer insulating layer ILD1, and/or the gate insulating layer GI. In an embodiment, one of the first and second transistor electrodes TE1 and TE2 may be a source electrode, and the other thereof may be a drain electrode.

The first source drain conductive layer SD1 may be formed as a single layer or a multilayer made of at least one of aluminum (Al), molybdenum (Mo), chromium (Cr), gold (Au), titanium (Ti), nickel (Ni), neodymium (Nd), and an indium tin oxide (ITO) or an alloy thereof.

A first via layer VIA1 may be disposed on the first source drain conductive layer SD1. The first via layer VIA1 may be a single layer or a multilayer. For example, the first via layer VIA1 may include an organic material such as an acrylates resin, an epoxy resin, a phenolic resin, a polyamides resin, a polyimides resin, a polyesters resin, a polyphenylenesulfides resin, or a benzocyclobutene (BCB). However, it is not necessarily limited thereto, and the first via layer VIA1 may include a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), or a titanium oxide (TiOₓ), and various types of inorganic materials.

A second source drain conductive layer SD2 may be disposed on the first via layer VIAL The second source drain conductive layer SD2 may include a bridge pattern BRP. The bridge pattern BRP may serve to electrically connect the transistor M and the first electrode ET1 provided to the light emitting part EMU of the pixel PXL. For example, the bridge pattern BRP may be electrically connected to the first transistor electrode TE1 of the transistor M through a contact hole passing through the first via layer VIA1. The first electrode ET1 of the corresponding pixel PXL may be electrically connected to the bridge pattern BRP through a contact hole CNT passing through the second via layer VIA2 to be described later.

The second source drain conductive layer SD2 may be formed as a single layer or a multilayer made of at least one of aluminum (Al), molybdenum (Mo), chromium (Cr), gold (Au), titanium (Ti), nickel (Ni), neodymium (Nd), and an indium tin oxide (ITO) or an alloy thereof.

A second via layer VIA2 may be disposed on the second source drain conductive layer SD2. The second via layer VIA2 may be made of an organic material to flatten a lower step thereof. For example, the second via layer VIA2 may include an organic material such as an acrylates resin, an epoxy resin, a phenolic resin, a polyamides resin, a polyimides resin, a polyesters resin, a polyphenylenesulfides resin, or a benzocyclobutene (BCB). However, it is not necessarily limited thereto, and the second via layer VIA2 may include a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), or a titanium oxide (TiOₓ), and various types of inorganic materials.

The display element part DPL may be disposed on the second via layer VIA2.

The display element part DPL may include the light emitting part EMU including the first electrodes ET1, the light emitting elements LD, and the second electrodes ET2. The display element part DPL may further include a reflective layer 15, a bank BNK, a first organic layer OL1, and/or a second organic layer OL2 disposed around the light emitting elements LD, and a first passivation layer PSS1 covering the light emitting parts EMU.

For example, in each light emitting area EMA of the display element part DPL, at least one light emitting element LD forming the light emitting part EMU of the corresponding pixel PXL, and the first electrode ET1 and the second electrode ET2 electrically connected to the light emitting element LD may be disposed. For example, the display element part DPL may include the first electrode ET1 disposed in the first light emitting area EMA1 of the first pixel PXL1 and at least one light emitting element LD disposed on the first electrode ET1; the first electrode ET1 disposed in the second light emitting area EMA2 of the second pixel PXL2 and at least one light emitting element LD disposed on the first electrode ET1; the first electrode ET1 disposed in the third light emitting area EMA3 of the third pixel PXL3 and at least one light emitting element LD disposed on the first electrode ET1; and the second electrode ET2.

The first electrode ET1 of each pixel PXL may be disposed on the pixel circuit part PCL to be positioned in each light emitting area EMA. For example, the first electrode ET1 of the first pixel PXL1 may be disposed on the pixel circuit part PCL to be positioned in the first light emitting area EMA1, the first electrode ET1 of the second pixel PXL2 may be disposed on the pixel circuit part PCL to be positioned in the second light emitting area EMA2, and the first electrode ET1 of the third pixel PXL3 may be disposed on the pixel circuit part PCL to be positioned in the third light emitting area EMA3. In the embodiment, each first electrode ET1 may be an anode electrode provided in the corresponding pixel PXL (or the light emitting part EMU of the corresponding pixel PXL). The first electrodes ET1 of the pixels PXL may be separated from each other.

Each first electrode ET1 may be electrically connected to at least one circuit element forming the pixel circuit PXC of the corresponding pixel PXL. For example, the first electrode ET1 of the first pixel PXL1 may be electrically connected to at least one circuit element (for example, the transistor M of the first pixel PXL1) forming the pixel circuit PXC of the first pixel PXL1. Similarly, the first electrode ET1 of the second pixel PXL2 may be electrically connected to at least one circuit element (for example, the transistor M of the second pixel PXL2) forming the pixel circuit PXC of the second pixel PXL2, and the first electrode ET1 of the third pixel PXL3 may be electrically connected to at least one circuit element (for example, the transistor M of the third pixel PXL3) forming the pixel circuit (PXC) of the third pixel PXL3.

The first electrodes ET1 may be disposed on the second via layer VIA2. The first electrodes ET1 may be electrically connected to respective bridge patterns BRP through respective contact holes CNT.

Each first electrode ET1 may be disposed under or below the light emitting element LD provided in the corresponding pixel PXL, and may be electrically connected to the light emitting element LD. For example, each first electrode ET1 may be in contact with a first end portion EP1 of the light emitting element LD provided in the corresponding pixel PXL to be electrically connected to the first end portion EP1 of the light emitting element LD. In the embodiment, the first end portion EP1 may be a portion of the light emitting element LD including a first semiconductor layer 11 of the light emitting element LD and/or at least one electrode layer provided therearound.

Each first electrode ET1 may transmit an electrical signal provided through the pixel circuit PXC of the corresponding pixel PXL to the first end portion EP1 of the light emitting element LD. For example, the first electrode ET1 may transmit the voltage of the first power source VDD supplied through each pixel circuit PXC to the first semiconductor layer 11 of the light emitting element LD provided in the corresponding pixel PXL.

In an embodiment, each first electrode ET1 may include a bonding metal that is bonded to each light emitting element LD. The first electrode ET1 may have conductivity by including at least one conductive material, and the constituent material thereof is not particularly limited. For example, the first electrode ET1 may include at least one of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), and copper (Cu), or other conductive material.

In an embodiment, the first electrode ET1 may include a reflective conductive material. For example, the first electrode ET1 may be formed as a metal film including a metal having a high reflectance in a visible light wavelength band, for example, at least one of reflective metals including aluminum (Al), gold (Au), and silver (Ag). Accordingly, the light efficiency of the pixels PXL may be increased.

The light emitting elements LD of the pixels PXL may be disposed on the first electrode ET1. In the embodiment, the light emitting elements LD may be disposed on or directly disposed on respective first electrodes ET1 to be electrically connected to respective first electrodes ET1.

Each light emitting element LD may include a light emitting stack including the first semiconductor layer 11, an active layer 12, and a second semiconductor layer 13 sequentially disposed on each first electrode ET1. Each light emitting element LD may further include an additional layer 14. For example, the light emitting element LD may include the first semiconductor layer 11, the active layer 12, and the second semiconductor layer 13 that may be sequentially stacked each other in a direction from the first end portion EP1 adjacent to each first electrode ET1 to a second end portion EP2 adjacent to each second electrode ET2.

In the embodiment, each light emitting element LD may be manufactured in a pillar shape through an etching method or the like, and bonded onto each of the first electrodes ET1. For example, the pillar shape may include a rod-like shape or bar-like shape such as a circular pillar or a polygonal pillar, and a shape of a cross-section thereof is not particularly limited.

In the embodiment, the light emitting element LD may have a size as small as nano-scale or micro-scale. However, the size of the light emitting element LD is not limited thereto.

The first semiconductor layer 11 may include a first conductive type of semiconductor layer including a first conductive type of dopant. For example, the first semiconductor layer 11 may be a p-type semiconductor layer including a p-type dopant. In the embodiment, the first semiconductor layer 11 may be positioned at the first end portion EP1 of the light emitting element LD.

In the embodiment, the first semiconductor layer 11 may include a nitride-based semiconductor material or a phosphide-based semiconductor material. For example, the first semiconductor layer 11 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. In the embodiment, the first semiconductor layer 11 may include a p-type of dopant such as Mg. The material included in the first semiconductor layer 11 is not limited thereto, and in addition to this, various materials may be used to form the first semiconductor layer 11.

The active layer 12 may be interposed between the first semiconductor layer 11 and the second semiconductor layer 13. The active layer 12 may include a single or multiple quantum well structure. In the embodiment, when the active layer 12 is formed in a multi-quantum well structure, the active layer 12 may have a structure in which a barrier layer, a strain reinforcing layer, and a well layer may be periodically and/or repeatedly stacked each other as one unit. However, the structure of the active layer 12 is not limited to the above-described embodiment.

When a voltage of a threshold voltage or more is applied to both ends of the light emitting element LD, light may be emitted while electron-hole pairs are recombined in the active layer 12. For example, when an electrical signal is applied to the active layer 12 through the first semiconductor layer 11 and the second semiconductor layer 13, as electron-hole pairs are recombined in the active layer 12, light of a specific or given color and a corresponding wavelength band may be emitted.

In the embodiment, the active layer 12 may emit light of a visible ray wavelength band, for example, light having a wavelength in a range of about 400 nm to about 900 nm. For example, the active layer 12 may emit blue light having a wavelength ranging from about 450 nm to about 480 nm, green light having a wavelength ranging from about 480 nm to about 560 nm, or red light having a wavelength ranging from about 620 nm to about 750 nm. The color and/or wavelength band of the light generated by the active layer 12 may be changed.

In the embodiment, the active layer 12 may include a nitride-based semiconductor material or a phosphide-based semiconductor material. For example, the active layer 12 may include a nitride-based semiconductor material including at least one of GaN, AlGaN, InGaN, InGaAlN, AlN, InN, and AlInN, or a phosphide-based semiconductor material including at least one of GaP, GaInP, AlGaP, AlGaInP, AlP, and InP. The material included in the active layer 12 is not limited thereto, and in addition to this, various materials may be used to form the active layer 12.

The second semiconductor layer 13 may include a second conductive type of semiconductor layer including a second conductive type of dopant. For example, the second semiconductor layer 13 may be a p-type semiconductor layer including an n-type dopant. In the embodiment, the second semiconductor layer 13 may be positioned at the second end portion EP2 of the light emitting element LD.

In the embodiment, the second semiconductor layer 13 may include a nitride-based semiconductor material or a phosphide-based semiconductor material. For example, the second semiconductor layer 13 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. In the embodiment, the second semiconductor layer 13 may include an n-type of dopant such as Si, Ge, Sn, or the like within the spirit and the scope of the disclosure. The material included in the second semiconductor layer 13 is not limited thereto, and in addition to this, various materials may be used to form the second semiconductor layer 13.

In the embodiment, the first semiconductor layer 11 and the second semiconductor layer 13 may include a same semiconductor material, but may include dopants of different conductive types. In an embodiment, the first semiconductor layer 11 and the second semiconductor layer 13 may include different semiconductor materials, and may include dopants of different conductive types.

In the embodiment, the first semiconductor layer 11 and the second semiconductor layer 13 may have different thicknesses (or lengths) along the third direction DR3 (Z-axis direction). For example, in the third direction (Z-axis direction), the second semiconductor layer 13 may have a thickness larger than that of the first semiconductor layer 11. Accordingly, the active layer 12 may be positioned closer to the first end portion EP1 (for example, the p-type of end portion) than the second end portion EP2 (for example, the n-type of end portion).

The second semiconductor layer 13 may be disposed under or below the second electrode ET2 to be electrically connected to the second electrode ET2. When the pixels PXL share one second electrode ET2, the second semiconductor layers 13 provided in the light emitting elements LD of the pixels PXL may be commonly connected to one second electrode ET2.

Each light emitting element LD may further include an insulating film 14 surrounding an external circumferential surface (for example, a side surface) of the light emitting stack. For example, each light emitting element LD may further include the insulating film 14 provided on the surface of the light emitting element LD to surround the side surfaces of the first semiconductor layer 11, the active layer 12, and the second semiconductor layer 13. As respective insulating films 14 are provided in the light emitting elements LD, it is possible to reduce or prevent surface defects of the light emitting elements LD and prevent short circuit defects through the light emitting elements LD.

The insulating film 14 may expose at least a portion of the light emitting stack at the first end portion EP1 and the second end portion EP2. Accordingly, the light emitting element LD may be electrically connected to each of the first electrode ET1 and the second electrode ET2.

The insulating film 14 may include a transparent insulating material. Accordingly, light generated by each active layer 12 may transmit through the insulating film 14 to be emitted to the outside of the light emitting element LD. For example, the insulating film 14 may be a double layer, and respective layers forming the double layer may include different materials. For example, the insulating film 14 may be formed as a double layer made of an aluminum oxide (AlOₓ) and a silicon oxide (SiOₓ), but is not limited thereto.

The first organic layer OL1 may be disposed on the first electrode ET1 and the light emitting element LD. The first organic layer OL1 may serve to fix the light emitting element LD on the first electrode ET1. The first organic layer OL1 may include an organic material such as an acrylates resin, an epoxy resin, a phenolic resin, a polyamides resin, a polyimides resin, a polyesters resin, a polyphenylenesulfides resin, or a benzocyclobutene (BCB), but is not necessarily limited thereto.

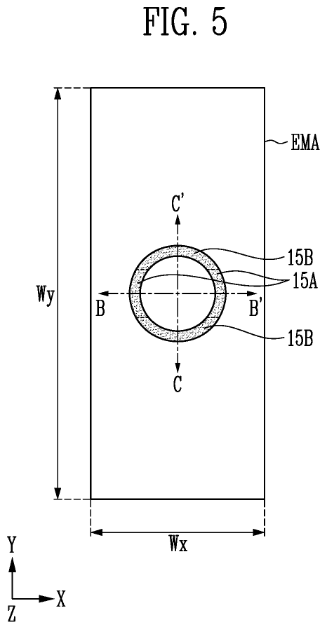

The reflective layer 15 may be disposed on the light emitting element LD. For example, the reflective layer 15 may be disposed on or directly disposed on the surface of the light emitting element LD. The reflective layer 15 may be disposed to surround the light emitting element LD. The reflective layer 15 may be disposed on a side surface of the light emitting element LD, and may expose the first end portion EP1 and the second end portion EP2 of the light emitting element LD. The reflective layer 15 may reflect light emitted from the light emitting element LD to guide it in the third direction (Z-axis direction), for example, in the front direction of the display panel PNL, thereby improving light output efficiency. The material of the reflective layer 15 is not particularly limited, and the reflective layer 15 may be made of various reflective materials. Hereinafter, the reflective layer 15 will be described in detail with reference to FIG. 5 to FIG. 7.

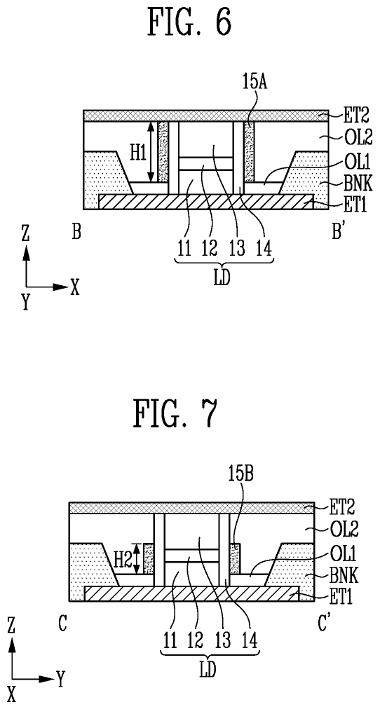

FIG. 5 illustrates a schematic top plan view of a reflective layer according to an embodiment. FIG. 6 illustrates a schematic cross-sectional view taken along line B-B′ of FIG. 5. FIG. 7 illustrates a schematic cross-sectional view taken along line C-C′ of FIG. 5.

Referring to FIG. 5 to FIG. 7, a width Wx of a first direction (an X-axis direction) of the light emitting area EMA and a width Wy of a second direction (a Y-axis direction) of the light emitting area EMA may be different. For example, the width Wx of the first direction (X-axis direction) of the light emitting area EMA may be smaller than the width Wy of the second direction (Y-axis direction) thereof.

The reflective layer 15 may be formed to have different heights (or thicknesses) according to the width of the light emitting area EMA. For example, the reflective layer 15 may include first areas 15A facing each other in the first direction (X-axis direction) and second areas 15B facing each other in the second direction (Y-axis direction). A height H1 in the third direction (Z-axis direction) of the first area 15A of the reflective layer 15 and a height H2 in the third direction (Z-axis direction) of the second area 15B may be different from each other. For example, when the width Wx in the first direction (X-axis direction) of the light emitting area EMA is smaller than the width Wy in the second direction (Y-axis direction), the height H1 of the first areas 15A of the reflective layer 15 in the third direction (Z-axis direction) may be greater than the height H2 of the second areas 15B in the third direction (Z-axis direction). In the embodiment, the second areas 15B of the reflective layer 15 may at least partially expose the light emitting element LD. For example, the second areas 15B of the reflective layer 15 may at least partially expose the second semiconductor layer 13.

As described above, a light intensity may be improved by relatively largely forming the heights of the first areas 15A of the reflective layer 15 facing each other in a direction that the width of the light emitting area EMA is narrow, for example, in the first direction (X-axis direction). Light loss caused by total reflection may be minimized by relatively small forming the heights of the second areas 15B of the reflective layer 15 facing each other in a direction that the width of the light emitting area EMA is wide, for example, in the second direction (Y-axis direction). For example, by differently forming the height of the reflective layer 15 according to the width of the light emitting area EMA, the light efficiency may be improved.

The bank BNK may be disposed between the first to third light emitting areas EMA1, EMA2, and EMA3, or at boundaries therebetween. For example, the bank BNK may overlap the non-light emitting area NEA.

The bank BNK may include at least one light blocking and/or reflective material. For example, the bank BNK may include at least one black matrix material and/or a color filter material of a specific or given color, and in addition to this, may include various materials.

The second organic layer OL2 may be disposed on the bank BNK. The second organic layer OL2 may be disposed on the first organic layer OL1. The second organic layer OL2 may be disposed between the light emitting elements LD of each pixel PXL. For example, the second organic layer OL2 may be disposed to surround the light emitting elements LD. The reflective layer 15 may be disposed between the light emitting element LD and the second organic layer OL2. The second organic layer OL2 may be disposed on or directly disposed on the reflective layer 15, but is not limited thereto.

The second organic layer OL2 may include an organic material such as an acrylates resin, an epoxy resin, a phenolic resin, a polyamides resin, a polyimides resin, a polyesters resin, a polyphenylenesulfides resin, or a benzocyclobutene (BCB), but is not necessarily limited thereto.

The second electrode ET2 may be disposed on the second organic layer OL2. For example, the pixels PXL may share one second electrode ET2. The second electrode ET2 may be electrically connected to the second semiconductor layer 13 of the light emitting elements LD. For example, the second electrode ET2 may be disposed on or directly disposed on the light emitting elements LD. For example, the second electrode ET2 may be formed on or directly formed on the second semiconductor layer 13 of the light emitting elements LD to be electrically connected to the second semiconductor layer 13. For example, the second electrode ET2 may be electrically connected to the second semiconductor layer 13 of the light emitting elements LD via at least one electrode layer or the like within the spirit and the scope of the disclosure.

The second electrode ET2 may have conductivity by including at least one conductive material. In the embodiment, the second electrode ET2 may include a transparent conductive material. For example, the second electrode ET2 may include at least one material of a conductive oxide such as an indium tin oxide (ITO), an indium zinc oxide (IZO), a zinc oxide (ZnO or ZnO2), an indium gallium zinc oxide (IGZO), or an indium tin zinc oxide (ITZO) and a conductive polymer such as poly(3,4-ethylenedioxythiophene (PEDOT), or other transparent conductive material. The second electrode ET2 may be substantially transparent. Accordingly, light output efficiency (for example, a front light output rate) of light generated by each light emitting element LD may be increased. The second electrode ET2 may be a single layer or a multilayer, and the shape, structure, and/or size thereof are not particularly limited.

The first passivation layer PSS1 may be disposed on the second electrode ET2. In the embodiment, the first passivation layer PSS1 may include at least one insulating material, and may be a single layer or a multilayer. For example, the first passivation layer PSS1 may include an organic insulating material, and may planarize the surface of the display element part DPL.

The light controller LCP may be disposed on the display element part DPL. The light controller LCP may be disposed on a path where light generated from the light emitting elements LD is emitted.

In the embodiment, the light controller LCP may include a color converting layer CCL and a color filter layer CFL. For example, the light emitting elements LD emitting light of a third color (for example, blue color) may be disposed in the first pixel PXL1, the second pixel PXL2, and the third pixel PXL3, and a first wavelength converting pattern WCP1 and a second wavelength converting pattern WCP2 respectively including first color converting particles and second color converting particles may be provided on the first pixel PXL1 and the second pixel PXL2, respectively. Accordingly, a full-color image may be displayed in the display area DA. However, the disclosure is not limited thereto, the first pixel PXL1, the second pixel PXL2, and the third pixel PXL3 may include the light emitting elements LD emitting light of different colors. For example, the first pixel PXL1, the second pixel PXL2, and the third pixel PXL3 may include red, green, and blue light emitting elements LD, respectively.

The color converting layer CCL may be disposed on the first passivation layer PSS1. The color converting layer CCL may include a wavelength converting pattern WCP, a light transmitting pattern LTP, a first light blocking pattern LBP1, and a second passivation layer PSS2. The wavelength converting pattern WCP may include the first wavelength converting pattern WCP1 and the second wavelength converting pattern WCP2.

The first wavelength converting pattern WCP1 may be disposed to overlap the first light emitting area EMA1 of the first pixel PXL1. For example, the first wavelength converting pattern WCP1 may be disposed within an opening of the first light blocking pattern LBP1.

The second wavelength converting pattern WCP2 may be disposed to overlap the second light emitting area EMA2 of the second pixel PXL2. For example, the second wavelength converting pattern WCP2 may be disposed within an opening of the first light blocking pattern LBP1.

The light transmitting pattern LTP may be disposed to overlap the third light emitting area EMA3 of the third pixel PXL3. For example, the light transmitting pattern LTP may be disposed within an opening of the first light blocking pattern LBP.

In the embodiment, the first light blocking pattern LBP1 may include openings overlapping respective light emitting areas EMA (for example, the first, second, and third light emitting areas EMA1, EMA2, and EMA3). The first wavelength converting pattern WCP1 may be disposed within the opening of the first light blocking pattern LBP1 overlapping the first light emitting area EMA1. The second wavelength converting pattern WCP2 may be disposed within the opening of the first light blocking pattern LBP1 overlapping the second light emitting area EMA2. The light transmitting pattern LTP may be disposed within the opening of the first light blocking pattern LBP1 overlapping the third light emitting area EMA3.

The first wavelength converting pattern WCP1 may include first color converting particles that convert the light of the third color emitted from the light emitting element LD provided in the first light emitting area EMA1 into light of the first color. For example, when the light emitting element LD provided in the first light emitting area EMA1 is a blue light emitting element emitting blue light and the first pixel PXL1 is a red pixel, the first wavelength converting pattern WCP1 may include a first quantum dot (for example, a red quantum dot) that converts blue light emitted from the blue light emitting element into red light. The type of the first color converting particles and the color and/or the wavelength of light converted in the first wavelength converting pattern WCP1 may be variously changed according to embodiments.

The second wavelength converting pattern WCP2 may include second color converting particles that convert the light of the third color emitted from the light emitting element LD provided in the second light emitting area EMA2 into light of the second color. For example, when the light emitting element LD provided in the second light emitting area EMA2 is a blue light emitting element emitting blue light and the second pixel PXL2 is a green pixel, the second wavelength converting pattern WCP2 may include a second quantum dot (for example, a green quantum dot) that converts blue light emitted from the blue light emitting element into green light. The type of the second color converting particles and the color and/or the wavelength of light converted in the second wavelength converting pattern WCP2 may be variously changed according to embodiments.

The light transmitting pattern LTP may be provided to efficiently emit light of a third color emitted from the light emitting element LD provided in the third light emitting area EMA3. For example, when the light emitting element LD provided in the third light emitting area EMA3 is a blue light emitting element emitting blue light and the third pixel PXL3 is a blue pixel, the light transmitting pattern LTP may include at least one type of light scattering particles (for example, silica or other light scattering particles) for increasing the light efficiency of the pixel PXL by scattering the blue light emitted from the blue light emitting element.

The light scattering particles do not have to be disposed only in the third light emitting area EMA3. For example, the light scattering particles may be selectively included in the first wavelength converting pattern WCP1 and/or the second wavelength converting pattern WCP2.

The first blocking pattern LBP1 may overlap the non-light emitting area NEA. In the embodiment, the first light blocking pattern LBP1 may be formed in a mesh-shaped pattern that surrounds each of the light emitting areas EMA in a plan view and may include openings corresponding to the light emitting areas EMA. The first light blocking pattern LBP1 may surround the wavelength converting patterns WCP and the light transmitting patterns LTP provided in respective light emitting areas EMA.

The first light blocking pattern LBP1 may include at least one light blocking material that may block transmission of light and may absorb light. For example, the first light blocking pattern LBP1 may include an organic material including at least one of graphite, carbon black, black pigment, or black dye, and at least one material of metals including chromium (Cr), or various other light blocking materials.

The second passivation layer PSS2 may be disposed on the wavelength converting patterns WCP and the light transmitting patterns LTP. In the embodiment, the second passivation layer PSS2 may include at least one insulating material, and may be a single layer or a multilayer. For example, the second passivation layer PSS2 may include an organic insulating material, and may substantially planarize the surface of the color converting layer CCL.

The color filter layer CFL may be disposed on the color converting layer CCL. A first color filter CF1 may be positioned on the light emitting element LD of the first pixel PXL1, and may selectively transmit light of the first color. For example, the first color filter CF1 may include a color filter material of the first color that transmits light of the first color and blocks transmission of light of the second color and the third color.

A second color filter CF2 may be positioned on the light emitting element LD of the second pixel PXL2, and may selectively transmit light of the second color. For example, the second color filter CF2 may include a color filter material of the second color that transmits light of the second color and blocks transmission of light of the first color and the third color.

A third color filter CF3 may be positioned on the light emitting element LD of the third pixel PXL3, and may selectively transmit light of the third color. For example, the third color filter CF3 may include a color filter material of the third color that transmits light of the third color and blocks transmission of light of the first color and the second color.

The second light blocking pattern LBP2 may surround the light emitting areas EMA (for example, the first, second, and third light emitting areas EMA1, EMA2, and EMA3). The second blocking pattern LBP2 may include openings overlapping the first, second, and third light emitting areas EMA1, EMA2, and EMA3. The openings of the second light blocking pattern LBP2 may correspond to the first, second, and third light emitting areas EMA1, EMA2, and EMA3, respectively. For example, the opening of the second light blocking pattern LBP2 may have a same or similar shape to the planar shape of the light emitting areas EMA (refer to FIG. 5). A width of the opening of the second blocking pattern LBP2 in the first direction (X-axis direction) may be different from a width of the opening of the second blocking pattern LBP2 in the second direction (Y-axis direction). For example, the width of the opening of the second light blocking pattern LBP2 in the first direction (X-axis direction) may be smaller than the width thereof in the second direction (Y-axis direction).

The first color filter CF1 may be disposed to overlap the first light emitting area EMA1 of the first pixel PXL1. For example, the first color filter CF1 may be disposed within the opening of the second light blocking pattern LBP2. The second color filter CF2 may be disposed to overlap the second light emitting area EMA2 of the second pixel PXL2. For example, the second color filter CF2 may be disposed within the opening of the second light blocking pattern LBP2. The third color filter CF3 may be disposed to overlap the third light emitting area EMA3 of the third pixel PXL3. For example, the third color filter CF3 may be disposed within the opening of the second light blocking pattern LBP2.

The second light blocking pattern LBP2 may include at least one light blocking material that may block transmission of light and may absorb light. For example, the second light blocking pattern LBP2 may include an organic material including at least one of graphite, carbon black, black pigment, or black dye, and at least one material of metals including chromium (Cr), or various other light blocking materials.

A planarization layer PLA may be formed on the color filter layer CFL. The planarization layer PLA may cover the color filters CF. The planarization layer PLA may substantially planarize a step caused by a lower member including the color filter layer CFL. The planarization layer PLA may include an organic insulating material. For example, the planarization layer PLA may include an organic material such as an acrylates resin, an epoxy resin, a phenolic resin, a polyamides resin, a polyimides resin, a polyesters resin, a polyphenylenesulfides resin, or a benzocyclobutene (BCB), but is not necessarily limited thereto.

Subsequently, a manufacturing method of the display device according to the above-described embodiment will be described.

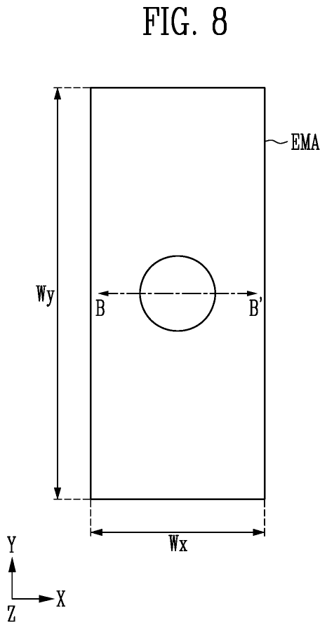

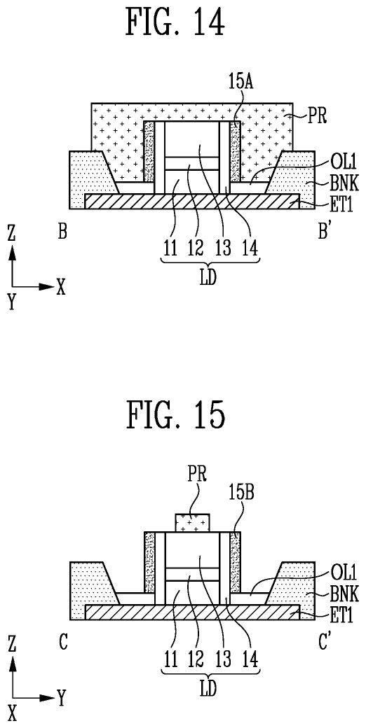

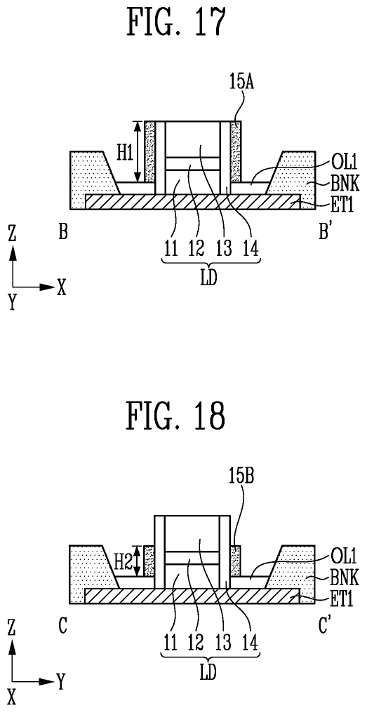

FIG. 8 to FIG. 20 illustrate schematic top plan views and schematic cross-sectional views of process steps of a manufacturing method of a display device according to an embodiment. FIG. 8 to FIG. 20 illustrate the manufacturing method of the display device with reference to FIG. 5 to FIG. 7, and constituent elements that are substantially the same as those of FIG. 5 to FIG. 7 are denoted by the same reference numerals, and detailed descriptions thereof may be omitted.

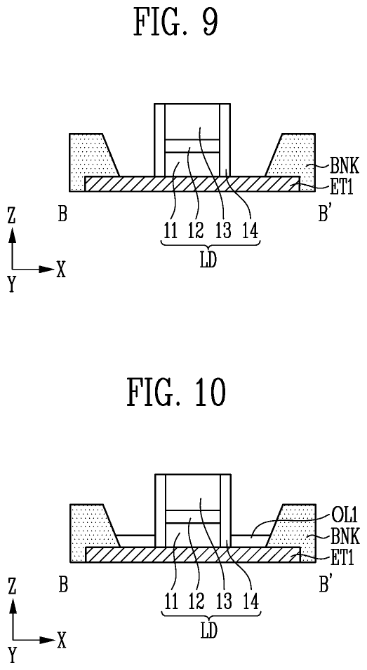

Referring to FIG. 8 and FIG. 9, first, the light emitting element LD is provided in the light emitting area EMA. The width Wx of the first direction (X-axis direction) of the light emitting area EMA and the width Wy of the second direction (Y-axis direction) of the light emitting area EMA may be different. For example, the width Wx of the first direction (X-axis direction) of the light emitting area EMA may be smaller than the width Wy of the second direction (Y-axis direction) thereof.

The light emitting element LD may be provided on the first electrode ET1 exposed by the bank BNK. The light emitting element LD may be provided on or directly provided on the first electrode ET1 to be electrically connected to the first electrode ET1.

Referring to FIG. 10, the first organic layer OL1 is formed on the first electrode ET1. The first organic layer OL1 may be formed on the first electrode ET1 to fix the light emitting element LD.

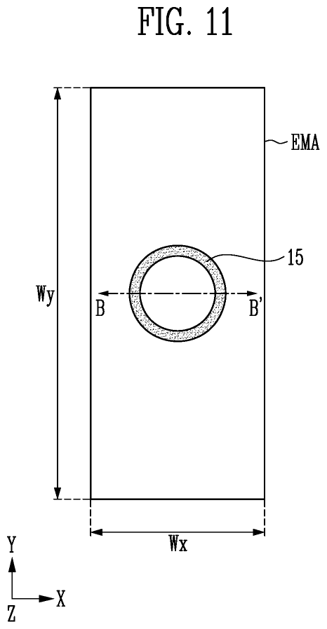

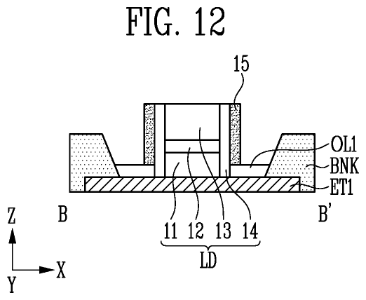

Referring to FIG. 11 and FIG. 12, the reflective layer 15 is formed on the light emitting element LD. The reflective layer 15 may be formed on or directly formed on the surface of the light emitting element LD. The reflective layer 15 may be disposed to surround the light emitting element LD. For example, the reflective layer 15 may be partially etched after being entirely deposited. Accordingly, the reflective layer 15 may be partially formed on the side surface of the light emitting element LD, and may expose the first end portion EP1 and the second end portion EP2 of the light emitting element LD. The reflective layer 15 may reflect light emitted from the light emitting element LD to guide it in the third direction (Z-axis direction), for example, in the front direction of the display panel PNL, thereby improving light output efficiency. The material of the reflective layer 15 is not particularly limited, and the reflective layer 15 may be made of various reflective materials.

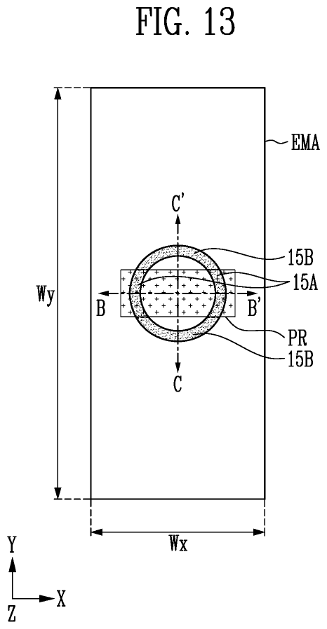

Referring to FIG. 13 to FIG. 15, a photoresist pattern PR is formed. The photoresist pattern PR may be partially formed on the light emitting element LD and the reflective layer 15. For example, when the width Wx of the first direction (X-axis direction) of the light emitting area EMA is smaller than the width Wy of the second direction (Y-axis direction) thereof, the photoresist pattern PR may be formed on the first areas 15A of the reflective layer 15 facing it in the first direction (X-axis direction). The photoresist pattern PR may expose the second areas 15B of the reflective layer 15 facing it in the second direction (Y-axis direction).

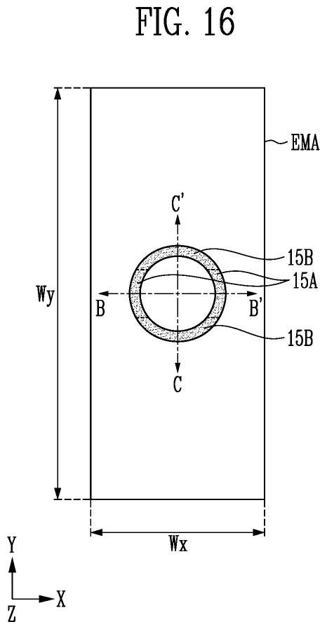

Referring to FIG. 16 to FIG. 18, subsequently, the second areas 15B of the reflective layer 15 are partially etched. By partially etching the second areas 15B of the reflective layer 15 exposed by the photoresist pattern PR, the height H1 of the first areas 15A of the reflective layer 15 in the third direction (Z-axis direction) may be greater than the height H2 of the second areas 15B thereof in the third direction (Z-axis direction). As described above, a light intensity may be improved by relatively largely forming the heights of the first areas 15A of the reflective layer 15 facing each other in a direction that the width of the light emitting area EMA is narrow, for example, in the first direction (X-axis direction). Light loss caused by total reflection may be minimized by relatively small forming the heights of the second areas 15B of the reflective layer 15 facing each other in a direction that the width of the light emitting area EMA is wide, for example, in the second direction (Y-axis direction). For example, as described above, by differently forming the height of the reflective layer 15 according to the width of the light emitting area EMA, the light efficiency may be improved.

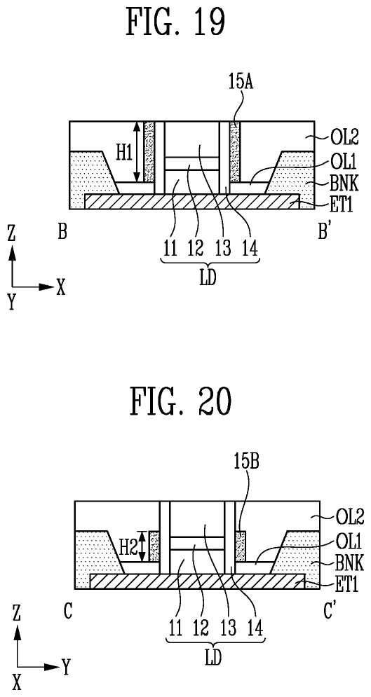

Referring to FIG. 19 and FIG. 20, the second organic layer OL2 is formed. The second organic layer OL2 may be formed on the bank BNK, the first organic layer OL1, and the reflective layer 15. For example, the second organic layer OL2 may be formed to surround the light emitting element LD and the reflective layer 15. The second organic layer OL2 may be formed on or directly formed on the reflective layer 15, but is not limited thereto.

As described above with reference to FIG. 4, the second electrode ET2 is formed on the light emitting element LD and the second organic layer OL2, and the color converting layer CCL is formed on the display element part DPL. For example, the first wavelength converting pattern WCP1 may be formed in the opening of the first light blocking pattern LBP1 overlapping the first pixel PXL1, the second wavelength converting pattern WCP2 may be formed in the opening of the first light blocking pattern LBP1 overlapping the second pixel PXL2, and the light transmitting pattern LTP may be formed in the opening of the first light blocking pattern LBP1 overlapping the third pixel PXL3.

The color filter layer CFL is formed on the color converting layer CCL. For example, the first color filter CF1 may be formed in the opening of the second light blocking pattern LBP2 overlapping the first pixel PXL1, the second color filter CF2 may be formed in the opening of the second light blocking pattern LBP2 overlapping the second pixel PXL2, and the third color filter CF3 may be formed in the opening of the second light blocking pattern LBP2 overlapping the third pixel PXL3.

In the embodiment, the second light blocking pattern LBP2 may be formed to surround the light emitting areas EMA (for example, the first, second, and third light emitting areas EMA1, EMA2, and EMA3). The second blocking pattern LBP2 may include openings overlapping the first, second, and third light emitting areas EMA1, EMA2, and EMA3. For example, the openings of the second light blocking pattern LBP2 may correspond to the first, second, and third light emitting areas EMA1, EMA2, and EMA3, respectively. For example, as described above with reference to FIG. 5, the opening of the second light blocking pattern LBP2 may have a same or similar shape as the planar shape of the light emitting areas EMA. The width of the opening of the second blocking pattern LBP2 in the first direction (X-axis direction) may be formed to be different from the width of the opening of the second blocking pattern LBP2 in the second direction (Y-axis direction). For example, the width of the opening of the second light blocking pattern LBP2 in the first direction (X-axis direction) may be smaller than the width thereof in the second direction (Y-axis direction).

Those skilled in the art will readily appreciate that many modifications are possible without departing from the disclosed teachings and advantages. The embodiments should be considered in a descriptive sense only and not for purposes of limitation. The scope of the disclosure, not by the detailed description given in the appended claims, and all differences within the equivalent scope will be construed as being included in the disclosure.

What is claimed is:

1. A display device comprising:
a light blocking layer surrounding a light emitting area;
a light emitting element disposed in the light emitting area; and
a reflective layer disposed on the light emitting element, wherein
a width of the light emitting area in a first direction is less than a width of the light emitting area in a second direction, and
heights of first areas of the reflective layer facing each other in the first direction are greater than heights of second areas of the reflective layer facing each other in the second direction.

2. The display device of claim 1, wherein the reflective layer is disposed directly on a surface of the light emitting element.

3. The display device of claim 1, wherein
the light blocking layer includes an opening having a same planar shape as the light emitting area, and
the display device further includes a color filter disposed in the opening of the light blocking layer.

4. The display device of claim 3, further comprising:
a color converting layer disposed between the light emitting element and the color filter.

5. The display device of claim 1, further comprising:
an organic layer surrounding the light emitting element.

6. The display device of claim 5, wherein the reflective layer is disposed between the light emitting element and the organic layer.

7. The display device of claim 6, wherein the organic layer is disposed directly on the reflective layer.

8. The display device of claim 1, wherein the light emitting element includes:
a first semiconductor layer;
a second semiconductor layer; and
an active layer disposed between the first semiconductor layer and the second semiconductor layer.

9. The display device of claim 8, wherein the second areas of the reflective layer at least partially expose the second semiconductor layer.

10. The display device of claim 8, further comprising:
a first electrode disposed on the first semiconductor layer; and
a second electrode disposed on the second semiconductor layer.

11. A manufacturing method of a display device, comprising:
providing a light emitting element in a light emitting area;
forming a reflective layer on the light emitting element;
forming a photoresist pattern on first areas of the reflective layer; and
partially etching second areas of the reflective layer, wherein
a width of the light emitting area in a first direction is less than a width of the light emitting area in a second direction, and
the first areas of the reflective layer face each other in the first direction, and the second areas of the reflective layer face each other in the second direction.

12. The manufacturing method of the display device of claim 11, further comprising:
forming a color filter on the light emitting element.

13. The manufacturing method of the display device of claim 12, further comprising:
forming a light blocking layer surrounding the light emitting area.

14. The manufacturing method of the display device of claim 13, wherein the light blocking layer includes an opening having a same planar shape as the light emitting area.

15. The manufacturing method of the display device of claim 14, wherein the color filter is formed in the opening of the light blocking layer.

16. The manufacturing method of the display device of claim 11, further comprising:
forming a color converting layer on the light emitting element.

17. The manufacturing method of the display device of claim 11, further comprising:
forming a first organic layer fixing the light emitting element.

18. The manufacturing method of the display device of claim 17, further comprising:
forming a second organic layer on the first organic layer.

19. The manufacturing method of the display device of claim 18, wherein the second organic layer surrounds the light emitting element.

20. The manufacturing method of the display device of claim 18, wherein the second organic layer is formed directly on the reflective layer.
